(19) United States
(12) Patent Application Publication
(10) Pub. No.: US 2026/0163332 A1
(43) Pub. Date: Jun. 11, 2026

(54) VCSEL COMPONENT AND METHOD FOR MANUFACTURING THE SAME

(71) Applicant: Taiwan-Asia Semiconductor Corporation, Hsinchu City (TW)

(72) Inventor: Shang-Che Lee, Hsinchu City (TW)

(21) Appl. No.: 19/296,091

(22) Filed: Aug. 11, 2025

(30) Foreign Application Priority Data
Dec. 11, 2024 (TW) 113148061

(51) Int. Cl. H01S 5/183; H01S 5/02; H01S 5/042

(52) U.S. Cl. CPC H01S 5/18313; H01S 5/0217; H01S 5/04256; H01S 5/18352

(57) ABSTRACT

The present invention provides a method for manufacturing a VCSEL component, which comprises the following steps: providing an indium phosphide substrate; performing an epitaxial procedure to form an epitaxial structure on the indium phosphide substrate, and the epitaxial structure includes an upper surface and a lower surface; performing a first mesa formation procedure to form a first mesa; performing a wet oxidation procedure to form a wet oxide layer in the first mesa; removing the indium phosphide substrate; performing a second mesa formation procedure to form a second mesa, with a gap formed between the first mesa and the second mesa; performing a deposition procedure to form an insulating layer on the epitaxial structure; and performing a metallization procedure to form an N-type electrode and a P-type electrode on the epitaxial structure, wherein the N-type electrode is positioned at the lower surface of the epitaxial structure, and the P-type electrode extends, along a lateral surface, from the upper surface to the lower surface of the epitaxial structure.

### CROSS REFERENCE TO RELATED APPLICATION

This application claims the benefit of Taiwan Patent Application Serial No. 113148061 filed on Dec. 11, 2024. The entirety of each Application is incorporated herein by reference.

### BACKGROUND OF THE INVENTION

### 1. Field of the Invention

The present invention relates to a VCSEL component and a method for manufacturing the same, particularly to a VCSEL component with simplified backend-of-line and improved heat dissipation efficiency and a method for manufacturing the same.

### 2. Description of Related Art

Laser diodes have the characteristic of emitting laser-like intense light with small volumes, and thus are widely used in various fields such as optical transmission, medical applications, 3D sensing and consumer electronics. Based on different directions of epitaxial growth and laser light resonance and emission, laser diodes can mainly be categorized into vertical-cavity surface-emitting lasers (VCSELs) and edge-emitting lasers (EELs). However, the VCSEL components have gradually become dominant for laser diodes in recent years, due to their higher optical purity and lower energy consumption compared to the EEL components.

Taking the well-known indium phosphide (InP) VCSEL component as an example, its overall structure forms a vertical mesa that facilitates executing various procedures. Nevertheless, packaging and wire bonding procedures are still necessary for the conventional InP VCSEL components in backend-of-line, which not only complicates the entire line but also makes costs higher. On the other hand, volumes and areas of the InP VCSEL components will be increased after packaging and wire bonding, which is detrimental to heat dissipation, inducing issues such as component failures.

In light of this, it is really worthy of research and development to design a VCSEL component and a method of manufacturing the same for solving those above-mentioned problems.

### SUMMARY OF THE INVENTION

An objective of the present invention is to provide a method for manufacturing for a VCSEL component with simplified backend-of-line and improved heat dissipation efficiency.

To achieve the above objective, the present invention provides a method for manufacturing the VCSEL component, comprising following steps. Provide an indium phosphide substrate. Perform an epitaxial growth procedure to form an epitaxial structure on the indium phosphide substrate, wherein the epitaxial structure includes an upper surface and a lower surface, and from where the lower surface is adjacent to the indium phosphide substrate, an N-type indium gallium arsenide layer, an N-type distributed Bragg reflector layer, an active region, a P-type distributed Bragg reflector layer and a P-type indium gallium arsenide layer are sequentially stacked for the epitaxial structure. Execute a first mesa forming procedure to form a first mesa from the upper surface of the epitaxial structure. Conduct a wet oxidation procedure to form a wet oxide layer within the first mesa. Remove the indium phosphide substrate. Execute a second mesa forming procedure to form a second mesa from the upper surface of the epitaxial structure, wherein a gap is formed between the first mesa and the second mesa. Perform a deposition procedure to form an insulating layer on the epitaxial structure. And conduct a metallization procedure to form an N-type electrode and a P-type electrode on the epitaxial structure, wherein the N-type electrode is located at the lower surface of the epitaxial structure and the P-type electrode extends, along a lateral surface, from the upper surface to the lower surface of the epitaxial structure.

In one embodiment of the present invention, the wet oxide layer is formed within the P-type distributed Bragg reflector layer and is adjacent to the active region.

In one embodiment of the present invention, the wet oxide layer is made of aluminum indium arsenide material.

In one embodiment of the present invention, the first mesa and the second mesa extend, from the upper surface towards the lower surface of the epitaxial structure, to the active region, such that the first mesa and the second mesa are coplanar by taking the N-type distributed Bragg reflector layer as a base.

In one embodiment of the present invention, the insulating layer is formed on all surfaces of the epitaxial structure except on the lower surface and except on the first top surface of the first mesa.

In one embodiment of the present invention, the P-type electrode extends from the first top surface of the first mesa, along the gap, the second top surface of the second mesa and the lateral surfaces of the epitaxial structure, to the lower surface, such that the N-type electrode and a portion of the P-type electrode both make contact with the lower surface.

The present invention further provides a VCSEL component. The VCSEL component of the present invention comprises an epitaxial structure, an insulating layer, an N-type electrode and a P-type electrode. The epitaxial structure includes an upper surface, a lower surface, a first mesa and a second mesa, wherein from the lower surface, an N-type indium gallium arsenide layer, an N-type distributed Bragg reflector layer, an active region, a P-type distributed Bragg reflector layer and a P-type indium gallium arsenide layer are sequentially stacked for the epitaxial structure, wherein the first mesa and the second mesa extend, from the upper surface toward the lower surface, to the active region, such that the first mesa and the second mesa are coplanar by taking the N-type distributed Bragg reflector layer as a base, with a gap formed between the second mesa and the first mesa, and wherein the first mesa has a wet oxide layer. The insulating layer is formed on the epitaxial structure. The N-type electrode is formed on the lower surface of the epitaxial structure. And the P-type electrode extends along a lateral surface, from the upper surface to the lower surface of the epitaxial structure.

### BRIEF DESCRIPTION OF THE DRAWINGS

FIG. 1 is a flowchart of a method for manufacturing a VCSEL component of the present invention;

FIG. 2 is a schematic diagram of each structure corresponding to each step of the method for manufacturing the VCSEL component of the present invention;

FIG. 3 is a schematic diagram of an overall structure of the VCSEL component of the present invention.

### DETAILED DESCRIPTION OF THE PREFERRED EMBODIMENT

Since various examples and embodiments in the present invention are only illustrative and non-restrictive, a person skilled in the art can easily conceive other examples and embodiments without contravening the scope of the present invention, after reading this specification, and can make the features and advantages of these embodiments more evident based on the following detailed description and claims.

Herein, the description of unit, element and component in the present invention uses “one”, “a”, or “an”. This is for convenience and for offering general meaning of the category of the present invention. Therefore, the description should be understood as including “one”, “at least one”, and singular and plural forms at the same time unless the context clearly indicates otherwise.

Herein, the description of the terms “first” or “second” and similar ordinal numbers are mainly used to distinguish or refer to the same or similar elements or structures and do not necessarily imply that such components or structures are spatially or temporally distinct order. It should be understood that ordinal numbers, in certain situations or configurations, may be used interchangeably without affecting the implementation of the present invention.

Herein, the description of “comprise”, “have” or other similar semantics have the non-exclusive meaning. For example, components or structures with a plurality of elements are not only limited to those disclosed in this specification, but also include generally inherent elements, which are not explicitly listed here for the components or the structures.

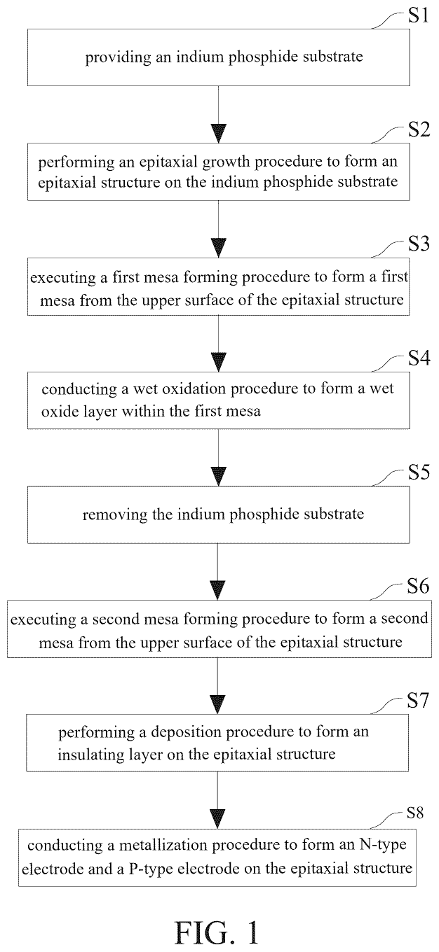

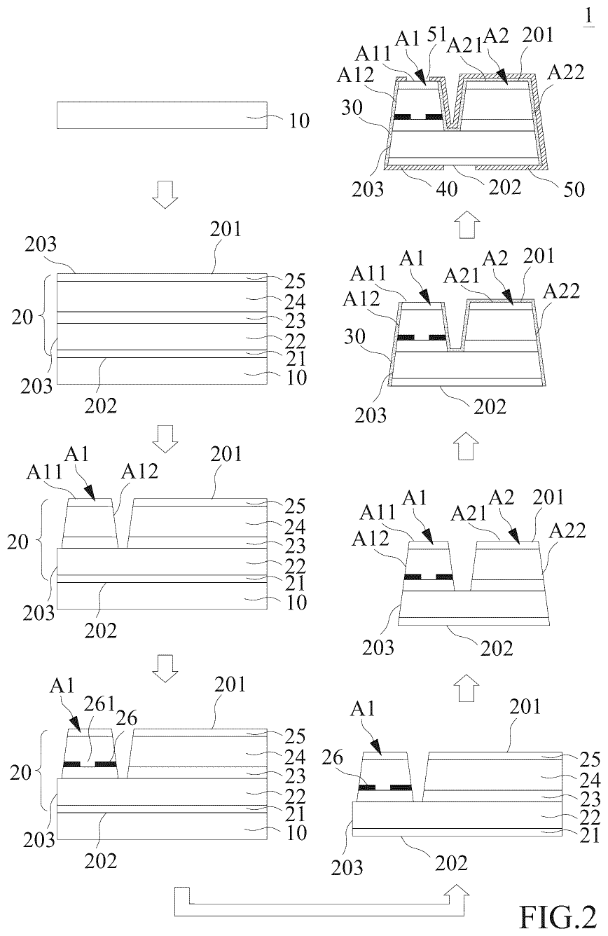

Please refer to FIG. 1 and FIG. 2 together. FIG. 1 is a flowchart of a method for manufacturing a VCSEL component of the present invention, and FIG. 2 is a schematic diagram of structures corresponding to steps of the method for manufacturing the VCSEL component of the present invention. As shown in FIG. 1 and FIG. 2, the method for manufacturing the VCSEL component of the present invention comprises following steps.

Step S1: providing an indium phosphide (InP) substrate.

First, an indium phosphide (InP) substrate 10 is provided for the present invention. The indium phosphide substrate 10 serves as a temporary substrate for a VCSEL component 1 of the present invention, for supporting related basic structures, subsequently formed, of the VCSEL component 1.

Step S2: performing an epitaxial growth procedure to form an epitaxial structure on the indium phosphide substrate.

After the indium phosphide substrate 10 in the previous step S1 is provided, epitaxial procedures, such as metal organic chemical vapor deposition (MOCVD), may be performed on the indium phosphide substrate 10 to form an epitaxial structure 20 for the present invention. The epitaxial structure 20 includes an upper surface 201 and a lower surface 202 opposite to each other, as well as multiple lateral surfaces 203 between the upper surface 201 and the lower surface 202. The epitaxial structure 20 is adjacent to the indium phosphide substrate 10 by the lower surface 202. In one embodiment of the present invention, from where the lower surface 202 is adjacent to the indium phosphide substrate 10, an N-type indium gallium arsenide (InGaAs) layer 21, an N-type distributed Bragg reflector (DBR) layer 22, an active region 23, a P-type distributed Bragg reflector (DBR) layer 24 and a P-type indium gallium arsenide (InGaAs) layer 25 are sequentially stacked for the epitaxial structure 20, with the upper surface 201 being on an opposite side of the P-type indium gallium arsenide layer 25. However, it is not limited for the present invention. And the N-type distributed Bragg reflector layer 22 is formed by stacking of multiple N-type semiconductor material layers, and the P-type distributed Bragg reflector layer 24 is formed by stacking of multiple P-type semiconductor material layers. In one embodiment of the present invention, the active region 23 is a multiple quantum well (MQW) layer.

Step S3: executing a first mesa forming procedure to form a first mesa from the upper surface of the epitaxial structure.

After the epitaxial structure 20 in the previous step S2 is formed, a first mesa forming procedure (e.g., etching or other related procedures) is next executed on the epitaxial structure 20 for the present invention, to form a first mesa A1 from the upper surface 201 of the epitaxial structure 20. The first mesa A1 extends from the upper surface 201 toward the lower surface 202 of the epitaxial structure 20, and reaches the active region 23, thereby forming an independent mesa structure. The first mesa A1 includes a first top surface A11 and multiple first lateral surfaces A12. Since horizontal cross-sectional areas of the first mesa A1 increases from top to bottom, each of the first lateral surfaces A12 is an inclined wall surface.

Step S4: conducting a wet oxidation procedure to form a wet oxide layer within the first mesa.

After the first mesa A1 in the previous step S3 is developed, a wet oxidation procedure is then conducted on the first mesa A1 to form a wet oxide layer 26 within the first mesa A1 for the present invention. In one embodiment of the present invention, the wet oxide layer 26 is formed within the P-type distributed Bragg reflector layer 24 and adjacent to the active region 23, and the wet oxide layer 26 has an opening region 261. The wet oxide layer 26 serves as a confinement layer for limiting electric current to flow only through the opening region 261, and light emitted by the active region 23 can also pass through the opening region 261 of the wet oxide layer 26 and can travel outward. In one embodiment of the present invention, the wet oxide layer 26 is made of aluminum indium arsenide (AlInAs) material, but the invention is not limited to this.

Step S5: removing the indium phosphide substrate.

After the wet oxide layer 26 within the first mesa A1 in the previous step S4 is disposed, the present invention is proceeded to remove the indium phosphide (InP) substrate 10, and only the epitaxial structure 20 with the formed first mesa A1 is retained.

Step S6: executing a second mesa forming procedure to form a second mesa from the upper surface of the epitaxial structure.

After the indium phosphide substrate 10 in the previous step S5 is removed, the present invention is continued to execute a second mesa forming procedure (such as etching or other related procedures) on the epitaxial structure 20 to form a second mesa A2 from the upper surface 201. The second mesa A2 extends from the upper surface 201 of the epitaxial structure 20 toward the lower surface 202, and reaches the active region 23, thereby forming an independent mesa structure. The second mesa A2 includes a second top surface A21 and multiple second lateral surfaces A22. Since horizontal cross-sectional areas of the second mesa A2 increases from top to bottom, each of the second lateral surfaces A22 is an inclined wall surface. Because the first mesa A1 and the second mesa A2 are independent from each other, a gap D is formed between the first mesa A1 and the second mesa A2. The second mesa A2 can be seen as an extension of the first mesa A1, and in fact, the first mesa A1 and the second mesa A2 are coplanar by taking the N-type distributed Bragg reflector layer 22 as a base.

In addition, during the procedure of forming the second mesa A2 in step S6, an outer contour of the first mesa A1 can also be modified, and the VCSEL component 1 to be formed can be diced for meeting required specifications.

Step S7: performing a deposition procedure to form an insulating layer on the epitaxial structure.

After the second mesa A2 in the previous step S6 is formed, a deposition procedure on the epitaxial structure 20 is next performed for the present invention, to form an insulating layer 30 on the epitaxial structure 20. In one embodiment of the present invention, the insulating layer 30 is formed on the all surfaces of the epitaxial structure 20, except on the lower surface 202 and except on the first top surface A11 of the first mesa A1. In other words, the insulating layer 30 will cover the multiple first lateral surfaces A12 of the first mesa A1, the second top surface A21 and multiple second lateral surfaces A22 of the second mesa A2, as well as the remaining lateral surfaces 203 of the epitaxial structure 20. In one embodiment of the present invention, the insulating layer 30 is made of silicon nitride (SiNx) material, but the invention is not limited thereto.

Step S8: conducting a metallization procedure to form an N-type electrode and a P-type electrode on the epitaxial structure.

After the insulating layer 30 in the previous step S7 is configured, a metallization procedure on the epitaxial structure 20 is then conducted for the present invention, to form an N-type electrode 40 and a P-type electrode 50 on the epitaxial structure 20. In one embodiment of the present invention, the N-type electrode 40 is located at the lower surface 202 of the epitaxial structure 20, and the P-type electrode 50 extends from the upper surface 201 of the epitaxial structure 20, along the lateral surfaces 203, to the lower surface 202. In one embodiment of the present invention, the P-type electrode 50 extends from the first top surface A11 of the first mesa A1 to the lower surface 202, along the gap D, the second top surface A21 of the second mesa A2 and the lateral surfaces 203 of the epitaxial structure 20, so that the N-type electrode 40 and a portion of the P-type electrode 50 are both in contact with the lower surface 202. In other words, in the VCSEL component 1 of the present invention, both the N-type electrode 40 and the portion of the P-type electrode 50 are positioned at the lower surface 202. Additionally, the P-type electrode 50 at the first top surface A11 of the first mesa A1 is formed with an opening 51, and the position of the opening 51 corresponds to the opening region 261 of the wet oxide layer 26, allowing the light emitted from the active region 23 to travel outward, sequentially through the opening region 261 of the wet oxide layer 26 and the opening 51 of the P-type electrode 50. In one embodiment of the present invention, the N-type electrode 40 is made of germanium gold (GeAu) material, and the P-type electrode 50 is made of titanium/platinum/gold (Ti/Pt/Au) material, but the invention is not limited to these materials.

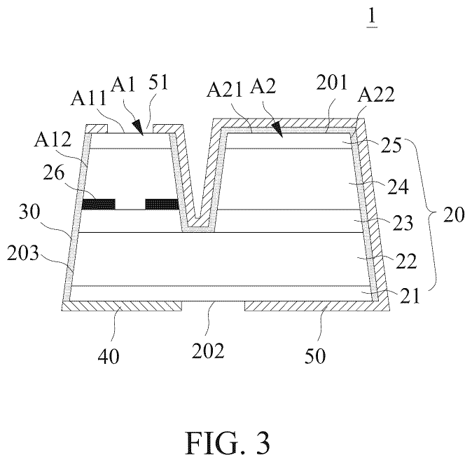

As shown in FIG. 3, the present invention further provides a VCSEL component 1. The VCSEL component 1 of the present invention can be fabricated by the aforementioned method for manufacturing. The VCSEL component 1 mainly comprises an epitaxial structure 20, an insulating layer 30, an N-type electrode 40 and a P-type electrode 50. The epitaxial structure 20 includes an upper surface 201, a lower surface 202, a first mesa A1 and a second mesa A2. An N-type indium gallium arsenide layer 21, an N-type distributed Bragg reflector layer 22, an active region 23, a P-type distributed Bragg reflector layer 24 and a P-type indium gallium arsenide layer 25 are sequentially stacked from the lower surface 202 for the epitaxial structure 20. The first mesa A1 and the second mesa A2 extend, from the upper surface 201 toward the lower surface 202, to the active region 23, making the first mesa A1 and the second mesa A2 coplanar by taking the N-type distributed Bragg reflector layer 22 as a base, with a gap formed between the second mesa A2 and the first mesa A1. The first mesa A1 includes a wet oxide layer 26. The insulating layer 30 is formed on the epitaxial structure 20. The N-type electrode 40 is formed on the lower surface 202 of the epitaxial structure 20. And the P-type electrode 50 extends along a lateral surface 203, from the upper surface 201 to the lower surface 202 of the epitaxial structure 20.

In one embodiment of the present invention, the wet oxide layer 26 is formed within the P-type distributed Bragg reflector layer 24 and is adjacent to the active region 23.

In one embodiment of the present invention, the VCSEL component 1 of the present invention is applied to long-wavelength light bands, such as an infrared light band, but the invention is not limited thereto.

In summary, for the VCSEL component 1 of the present invention, through emitting light from the first mesa A1 and by disposing of the wet oxide layer 26, a light emission efficiency is enhanced. Moreover, the second mesa A2 serves as an extended structure to facilitate disposing of the P-type electrode 50 and to allow the P-type electrode 50 extending from the upper surface 201 to the lower surface 202 of the epitaxial structure 20, so that an inverted electrode configuration is established. Since both the N-type electrode 40 and the P-type electrode 50 are present at the lower surface 202 of the VCSEL component 1, the VCSEL component 1 is able to be electrically activated simply by being disposed directly on corresponding devices or components, and thus additional wire bonding and packaging procedures for the N-type or P-type electrodes are not necessary. This results in a more compact overall size and reduces manufacturing costs compared to conventional VCSEL components. Furthermore, disposing of the second mesa A2 increases a contact area between the VCSEL component 1 and the corresponding devices or components, thereby providing a better heat dissipation performance.

The above implementations are only auxiliary descriptions, and are not intended to limit the embodiments of the application subject or the applications or uses of the embodiments. In addition, although at least one illustrative example has been presented above, it should be understood that the present invention can still have a large quantity of variations. It should also be understood that the embodiments described herein are not intended to limit the scope, use, or configuration of the requested subject matter in any way. On the contrary, the foregoing embodiments will provide a convenient guide for those skilled in the art to implement one or more embodiments. Furthermore, various changes can be made to the function and arrangement of the components without departing from the scope defined by the patent claims, and the scope of the patent claims includes known equivalents and all foreseeable equivalents at the time that the patent application is filed.

What is claimed is:

1. A method for manufacturing a VCSEL component, comprising following steps:
providing an indium phosphide substrate;
performing an epitaxial growth procedure to form an epitaxial structure on the indium phosphide substrate, wherein the epitaxial structure includes an upper surface and a lower surface, and from where the lower surface is adjacent to the indium phosphide substrate, an N-type indium gallium arsenide layer, an N-type distributed Bragg reflector layer, an active region, a P-type distributed Bragg reflector layer and a P-type indium gallium arsenide layer are sequentially stacked for the epitaxial structure;
executing a first mesa forming procedure to form a first mesa from the upper surface of the epitaxial structure;
conducting a wet oxidation procedure to form a wet oxide layer within the first mesa;
removing the indium phosphide substrate;
executing a second mesa forming procedure to form a second mesa from the upper surface of the epitaxial structure, wherein a gap is formed between the first mesa and the second mesa;
performing a deposition procedure to form an insulating layer on the epitaxial structure; and
conducting a metallization procedure to form an N-type electrode and a P-type electrode on the epitaxial structure, wherein the N-type electrode is located at the lower surface of the epitaxial structure and the P-type electrode extends, along a lateral surface, from the upper surface to the lower surface of the epitaxial structure.

2. The method for manufacturing the VCSEL component as claimed in claim 1, wherein the wet oxide layer is formed within the P-type distributed Bragg reflector layer and is adjacent to the active region.

3. The method for manufacturing the VCSEL component as claimed in claim 1, wherein the wet oxide layer is made of aluminum indium arsenide material.

4. The method for manufacturing the VCSEL component as claimed in claim 1, wherein the first mesa and the second mesa extend, from the upper surface towards the lower surface of the epitaxial structure, to the active region, such that the first mesa and the second mesa are coplanar by taking the N-type distributed Bragg reflector layer as a base.

5. The method for manufacturing the VCSEL component as claimed in claim 1, wherein the insulating layer is formed on all surfaces of the epitaxial structure except on the lower surface and except on the first top surface of the first mesa.

6. The method for manufacturing the VCSEL component as claimed in claim 1, wherein the P-type electrode extends from the first top surface of the first mesa, along the gap, the second top surface of the second mesa and the lateral surfaces of the epitaxial structure, to the lower surface, such that the N-type electrode and a portion of the P-type electrode both make contact with the lower surface.

7. A VCSEL component, comprising:
an epitaxial structure, including an upper surface, a lower surface, a first mesa and a second mesa, wherein from the lower surface, an N-type indium gallium arsenide layer, an N-type distributed Bragg reflector layer, an active region, a P-type distributed Bragg reflector layer and a P-type indium gallium arsenide layer are sequentially stacked for the epitaxial structure, wherein the first mesa and the second mesa extend, from the upper surface toward the lower surface, to the active region, such that the first mesa and the second mesa are coplanar by taking the N-type distributed Bragg reflector layer as a base, with a gap formed between the second mesa and the first mesa, and wherein the first mesa has a wet oxide layer;
an insulating layer, formed on the epitaxial structure;
an N-type electrode, formed on the lower surface of the epitaxial structure; and
a P-type electrode, extending, along a lateral surface, from the upper surface to the lower surface of the epitaxial structure.

8. The VCSEL component as claimed in claim 7, wherein the wet oxide layer is formed within the P-type distributed Bragg reflector layer and is adjacent to the active region.

9. The VCSEL component as claimed in claim 7, wherein the wet oxide layer is made of aluminum indium arsenide material.

10. The VCSEL component as claimed in claim 7, wherein the insulating layer is formed on all surfaces of the epitaxial structure except on the lower surface and except on the first top surface of the first mesa.

11. The VCSEL component as claimed in claim 7, wherein the P-type electrode extends from the first top surface of the first mesa, along the gap, the second top surface of the second mesa and the lateral surfaces of the epitaxial structure, to the lower surface, such that the N-type electrode and a portion of the P-type electrode both make contact with the lower surface.
